(19) United States
(12) Patent Application Publication
(10) Pub. No.: US 2010/0074450 A1
(43) Pub. Date: Mar. 25, 2010

(54) SYSTEM FOR ADJUSTING PLAYING VOLUME AUTOMATICALLY AND METHOD FOR THE SAME

(76) Inventor: Shiun-Chih Liao, Taichung City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 12/235,911

(22) Filed: Sep. 23, 2008

(51) Int. Cl. H03G 3/20

(52) U.S. Cl. 381/57; 381/104

(57) ABSTRACT

A system for adjusting playing volume automatically according to ambient sound and a method for the same are provided. The system includes a volume sensing unit, a volume adjustment database, a time data unit, an audio frequency module, and a volume control unit. The volume sensing unit detects for a change of ambient sound and generates a sensing signal. The time data unit generates a current time data. The volume adjustment database is built-in and configured for storing an audio variation data. The audio frequency module receives or outputs an audio signal. The volume control unit retrieves the sensing signal, the audio variation data, and the current time data, adjusts the audio variation data according to the sensing signal, and controls variation of the audio signal outputted in real time, so as to enable automatic adjustment of playing volume and enchant audience.

### BACKGROUND OF THE INVENTION

1. Field of the Invention

The present invention relates to a system for adjusting playing volume automatically and a method for the same, and more particularly, to a system for adjusting playing volume automatically according to ambient sound and a method for the same.

2. Description of the Prior Art

Ever-changing technology accompanies progress and changes in advertisement. The advertisement industry is innovative not only in contents of advertisements but also in vehicles of advertisement. For instance, existing vehicles of advertisement are, namely flyers, newspaper advertisement, TV advertisement, online advertisement, mobile advertisement, etc. An emerging vehicle of advertisement is an advertisement player for playing advertisement messages in public.

In general, advertisement players are placed at venues with heavy traffic, such as on buses, at department store's elevator doors, or in crowded shopping malls. Passers-by are unwittingly impressed by advertisement messages played by advertisement players installed at specific venues on a long-term basis for ceaseless, iterative delivery of advertisement messages, uninvited and repeated.

Known advertisement players are selectively operated by two different systems. The first system plays advertisement messages with a player and then displays the messages on a liquid crystal display (LCD). The second system sends advertisement messages to a set top box (STB) at a client end by the Internet, transmits the advertisement messages from the STB to the LCD, and plays the advertisement messages received by the LCD.

The latter is flexible and expandable. However, both systems have a vulnerable drawback in common, that is, neither of the systems can provide playing volume that varies with ambient volume. For instance, the level of noise around elevators in department stores varies with the number of elevator users, and thus sometimes the noise can be great enough to drown the playing volume of any advertisement players installed at the elevators; as a result, not only are advertisement messages undelivered, but advertisement messages become inconspicuous. In conclusion, advertisement players of the prior art have the following drawbacks:
1. incapable of adjusting playing volume automatically
2. inefficient delivery of advertisement messages
3. inconspicuous advertisement messages

Hence, the inventor of this application and related manufacturers stand in need of an immediate solution of the aforesaid problems and drawbacks of the prior art.

### SUMMARY OF THE INVENTION

To solve the aforesaid problems, it is a primary objective of the present invention to provide a system for adjusting playing volume automatically according to ambient sound and a method for the same, wherein a volume control unit retrieves a sensing signal and a current time data generated by a volume sensing unit and a time data unit, respectively, and an audio variation data stored in a built-in volume adjustment database, and then the audio variation data is adjusted according to the sensing signal, thereby controlling variation of the audio signal outputted in real time.

To solve the aforesaid problems, it is another objective of the present invention to provide a system for adjusting playing volume automatically according to ambient sound and a method for the same. The system comprises a volume sensing unit for detecting a change of ambient sound and generating a sensing signal, an audio frequency module for receiving or outputting an audio signal, a volume adjustment database built-in and configured for storing an audio variation data, a time data unit for generating a current time data, and a volume control unit for retrieving the sensing signal, the audio variation data, and the current time data, adjusting the audio variation data according to the sensing signal, and controlling variation of the audio signal outputted in real time, so as to enable automatic adjustment of playing volume, enchant audience, and enhance delivery of messages.

Yet another objective of the present invention is to provide a method for adjusting playing volume automatically according to ambient sound. The method comprises retrieving, by a volume control unit, a sensing signal and a current time data generated by a volume sensing unit and a time data unit, respectively, and an audio variation data stored in a volume adjustment database; and determining, by the volume control unit and according to comparison between the currently retrieved sensing signal and audio variation data, whether the audio variation data and playing volume should be currently adjusted, and generating, according to a result of the determining, a control signal for controlling variation of an audio signal outputted by an audio frequency module in real time, so as to enable automatic adjustment of playing volume, enchant audience, and enhance delivery of messages.

The characteristics and technical features of the present invention will be best understood by reference to the following detailed description of an illustrative embodiment when read in conjunction with the accompanying drawings. The accompanying drawings are only illustrative of the present invention but are not intended to restrict the scope of the present invention.

### BRIEF DESCRIPTION OF THE DRAWINGS

FIG. 1 is a block diagram of a system of the present invention;

FIG. 2 is a block diagram of a loudspeaker unit and a system of the present invention;

FIG. 3 is a block diagram of a loudspeaker unit of a display device and a system of the present invention; and

FIG. 4 is a flow chart of the present invention.

### DETAILED DESCRIPTION OF THE EMBODIMENTS

The objectives, structural features, and functional features of the present invention are illustrated with the preferred embodiments shown in the accompanying drawings.

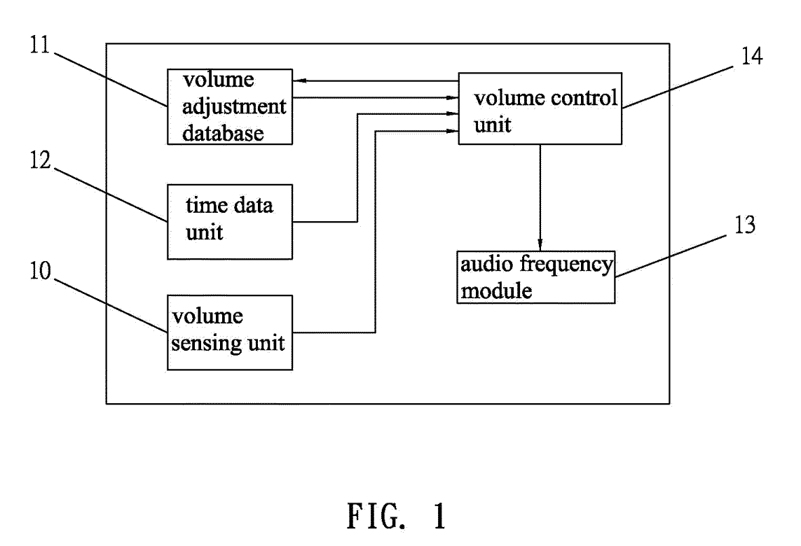

The present invention provides a system for adjusting playing volume automatically according to ambient sound and a method for the same. Referring to FIG. 1, in a preferred embodiment of the present invention, the system comprises a volume sensing unit 10, a volume adjustment database 11, a time data unit 12, an audio frequency module 13, and a volume control unit 14. The volume sensing unit 10 is a microphone sensor that detects for variation of ambient sound (that is, retrieves the level of volume of ambient sound) in real time and generates a sensing signal. The volume adjustment database 11 is built-in and configured for storing an audio variation data. The time data unit 12 generates a current time data. The audio frequency module 13 receives an audio signal and outputs the audio signal.

The volume control unit 14 retrieves (or reads) the sensing signal, the audio variation data, and the current time data so as to perform computation thereon, adjusts the audio variation data according to the sensing signal so as to generate a control signal, and controls variation of the audio signal outputted by the audio frequency module 13 according to the control signal in real time. Hence, the system of the present invention enables automatic adjustment of playing volume, enchants audience, and enhances delivery of advertisement messages. Hence, the present invention effectively solves the drawbacks of the prior art, namely incapable of adjusting playing volume automatically, inefficient delivery of advertisement messages, and inconspicuous advertisement messages.

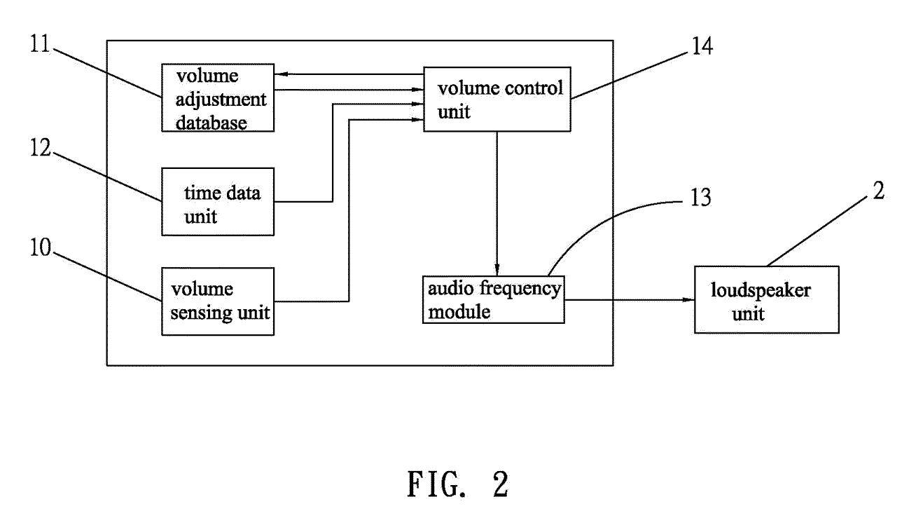

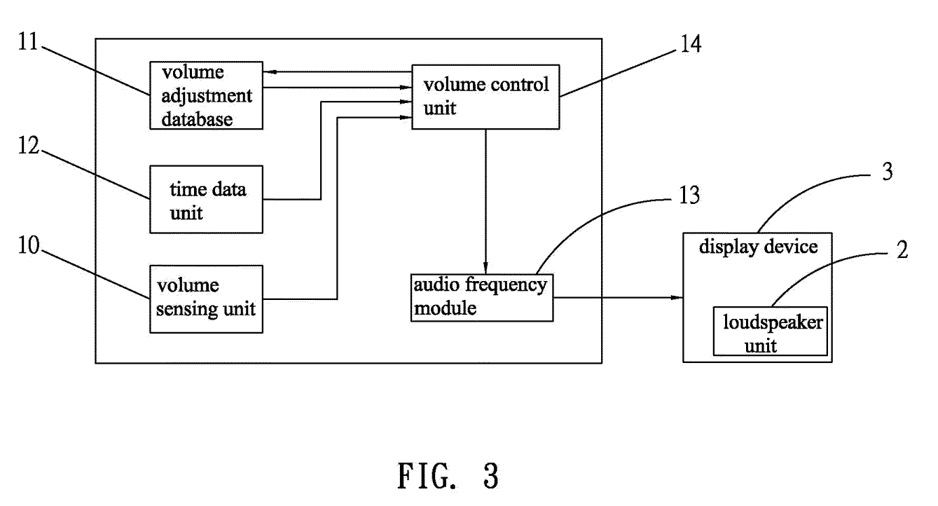

Refer to FIGS. 2 and 3 for the following description. The sensing signal generated by the volume sensing unit 10 has at least an external decibel (dB) level; the external decibel level denotes a current ambient decibel level detected by the volume sensing unit 10. The audio variation data stored in the volume adjustment database 11 comprises at least a predetermined time and at least a decibel level corresponding to the predetermined time. The predetermined times are equal and/or unequal in decibel level. The predetermined times with equal decibel level are exemplified by 10˜20 decibels at a first predetermined time (10:00˜11:00) and 10˜20 decibels at a second predetermined time (11:00˜12:00). Conversely, the predetermined times with unequal decibel level are exemplified by 10˜20 decibels at a first predetermined time (12:00˜13:00) and 30˜40 decibels at a second predetermined time (13:00˜14:00). In practice, the present invention is not limited to the above disclosures.

The audio frequency module 13 is electrically connected to a display device 3, allowing the audio signal outputted by the audio frequency module 13 to be displayed by a loudspeaker unit 2 of the display device 3. Increased/decreased playing volume of the loudspeaker unit 2 corresponds in magnitude to variation of the audio signal. The display device 3 is a liquid crystal display (LCD) or a plasma display panel.

Alternatively, the audio frequency module 13 is electrically connected to a loudspeaker unit 2, allowing the audio signal outputted by the audio frequency module 13 to be displayed by the loudspeaker unit 2. Increased/decreased playing volume of the loudspeaker unit 2 corresponds in magnitude to variation of the audio signal. The loudspeaker unit 2 is a loudspeaker.

Furthermore, the system is configured for use with a set top box (STB) device (not shown) so as to control variation of the audio signal outputted by the STB device in real time. The present preferred embodiment is exemplified by a set top box (STB), though, in practice, the present invention is not limited to the above disclosures.

The present invention is illustrated with an exemplification as follows:

Where an advertisement agent installs the STB at a venue fit for delivery of advertisement messages, such as the entrance to or elevator doors in a department store, and applies the system of the present invention to the STB, the advertisement agent may set playing volume level (the decibel level) for each period of time (the predetermined time) in light of volume of shopper traffic during each period of time. In the present preferred embodiment, the playing volume level is set for each period of time from 10:00 in the morning to 22:00 in the late evening; for example, setting the playing volume level during both the period 10:00˜12:00 in the morning and the period 12:00˜14:00 at noon and in the early afternoon to 10˜20 decibels, setting the playing volume level during the periods 14:00˜16:00 and 16:00˜18:00 in the afternoon to 20˜30 decibels and 30˜40 decibels, respectively, and setting the playing volume level during the period 18:00˜20:00 in the early evening to 40˜50 decibels and the period 20:00˜22:00 in the late evening to 50˜60 decibels and above. In practice, the present invention is not limited to the above disclosures.

If it is currently 13:00 at noon, the volume control unit 14 will retrieve the current time data (13:00), the sensing signal, and the predetermined time (12:00˜14:00) and decibel level (10˜20 decibels) of the audio variation data in sequence so as to perform computation thereon, and will compare the decibel level (10˜20 decibels) with the external decibel level (25 decibels) of the sensing signal. If the external decibel level exceeds the decibel level, the volume control unit 14 will instantly generate a read signal and send the read signal to the volume adjustment database 11. Depending on the received read signal, the volume adjustment database 11 sends to the volume control unit 14 another decibel level (20˜30 decibels) corresponding in magnitude to the external decibel level. The volume control unit 14 performs computation on the received another decibel level, the current time data, and the sensing signal again so as to generate the control signal. Then, depending on the control signal, the volume control unit 14 controls the audio signal sent from the audio frequency module 13 to the loudspeaker unit 2 of the display device 3; meanwhile, the loudspeaker unit 2 of the display device 3 receives variation of the audio signal, allowing the playing volume level (20˜30 decibels) to be changed.

If the external decibel level (15 decibels) does not exceed the decibel level (10˜20 decibels), the volume control unit 14 will perform computation on the current time data, the sensing signal, and the predetermined time (12:00˜14:00) and decibel level (10˜20 decibels) of the audio variation data so as to generate the control signal. Then, depending on the control signal, the volume control unit 14 controls the audio signal sent from the audio frequency module 13 to the loudspeaker unit 2 of the display device 3; meanwhile, the loudspeaker unit 2 of the display device 3 receives variation of the audio signal, allowing the playing volume level (10˜20 decibels) to be changed. Hence, the present invention effectuates automatic adjustment of playing volume, enchants audience, and enhances delivery of advertisement messages.

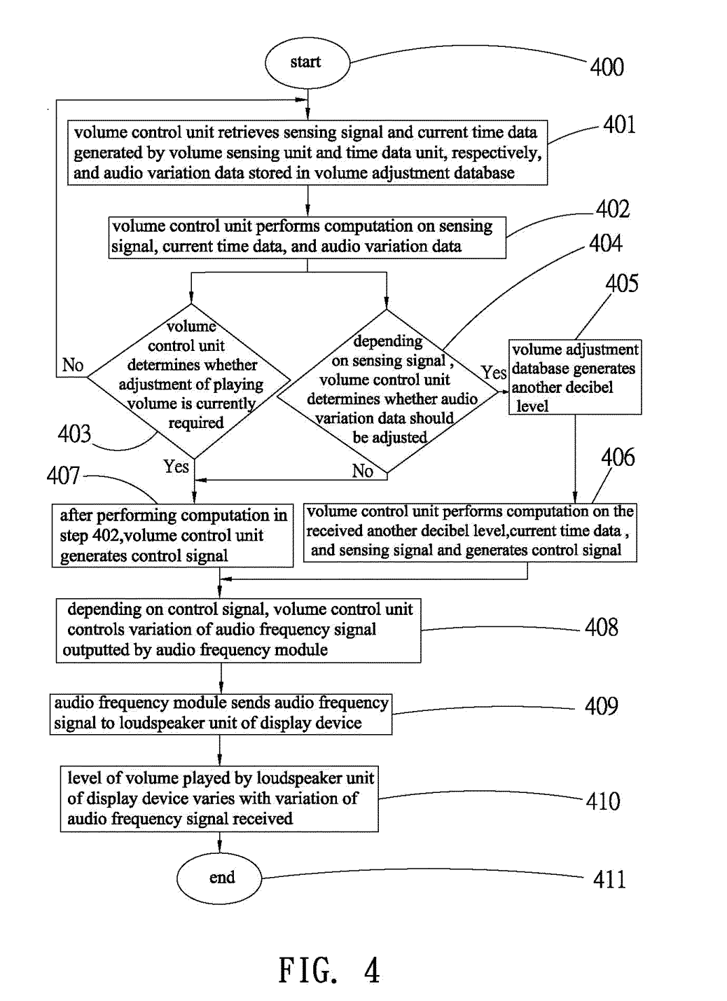

FIG. 4 depicts the specific steps in the preferred embodiment of adjusting playing volume automatically according to ambient sound as disclosed in the present invention. A system for adjusting playing volume automatically according to ambient sound and a method for the same are implemented in the following steps:
(400) start;
(401) a volume control unit 14 retrieves a sensing signal and a current time data generated by a volume sensing unit 10 and a time data unit 12, respectively, and an audio variation data stored in a volume adjustment database 11;
(402) the volume control unit 14 performs computation on the sensing signal, the current time data, and the audio variation data;
(403) the volume control unit 14 determines whether adjustment of playing volume is currently required; if the volume control unit 14 determines that the current time data (e.g., 10:00) is not beyond (or between) the predetermined time (e.g., 11:00˜12:00), the playing volume will not be adjusted; if the volume control unit 14 determines that the current time data (e.g., 13:00) is beyond the predetermined time (e.g., 11:00˜12:00), the playing volume will be adjusted; in case of affirmative determination, go to step 407; in case of negative determination, go to step 401;
(404) depending on the sensing signal, the volume control unit 14 determines whether the audio variation data should be adjusted; if the volume control unit 14 determines that the external decibel level (e.g., 30 decibels) of the sensing signal is beyond the decibel level (10˜20 decibels) of the audio variation data, the audio variation data will be adjusted; if the volume control unit 14 determines that the external decibel level (e.g., 30 decibels) of the sensing signal is not beyond (or between) the decibel level of the audio variation data, the audio variation data will not be adjusted; in case of affirmative determination, go to step 405; in case of negative determination, go to step 407;
(405) the volume control unit 14 instantly generates a read signal and sends the read signal to the volume adjustment database 11; and, depending on the received read signal, the volume adjustment database 11 sends to the volume control unit 14 another decibel level corresponding in magnitude to the external decibel level;
(406) the volume control unit 14 performs computation on the received another decibel level, the current time data, and the sensing signal and generates a control signal before going to step 408;
(407) after performing computation in step 402, the volume control unit 14 generates the control signal;
(408) depending on the control signal, the volume control unit 14 controls variation of the audio signal outputted by the audio frequency module 13;
(409) the audio frequency module 13 sends the audio signal to a loudspeaker unit 2 of a display device 3;
(410) the loudspeaker unit 2 of the display device 3 receives variation of the audio signal so as to allow level (or increment/decrement) of playing volume to be changed, thereby enabling automatic adjustment of playing volume, enchanting audience, and enhancing delivery of advertisement messages; and
(411) end.

In conclusion, the present invention provides a system for adjusting playing volume automatically according to ambient sound and a method for the same, which have the following advantages:
1. It enables automatic adjustment of playing volume
2. It enchants audience
3. It enhances delivery of advertisement messages

The foregoing preferred embodiments are only illustrative of the features and functions of the present invention but are not intended to restrict the scope of the present invention. It is apparent to those skilled in the art that all equivalent modifications and variations made in the foregoing preferred embodiments according to the spirit and principle in the disclosure of the present invention should fall within the scope of the appended claims.

What is claimed is:

1. A system for adjusting playing volume automatically according to ambient sound, comprising:
a volume sensing unit for detecting a change in ambient sound and generating a sensing signal;
a volume adjustment database being built-in and configured for storing an audio variation data;
a time data unit for generating a current time data;
an audio frequency module for receiving and outputting an audio signal; and
a volume control unit for retrieving the sensing signal, the audio variation data, and the current time data and adjusting the audio variation data according to the sensing signal so as to control variation of the audio signal outputted in real time.

2. The system for adjusting playing volume automatically according to ambient sound of claim 1, wherein the sensing signal has at least an external decibel level.

3. The system for adjusting playing volume automatically according to ambient sound of claim 1, wherein the audio variation data comprises at least a predetermined time and at least a decibel level corresponding to the predetermined time.

4. The system for adjusting playing volume automatically according to ambient sound of claim 1, wherein the predetermined times are equal or unequal in decibel level.

5. The system for adjusting playing volume automatically according to ambient sound of claim 1, wherein the volume sensing unit is a microphone sensor.

6. The system for adjusting playing volume automatically according to ambient sound of claim 1, wherein the audio frequency module is electrically connected to a loudspeaker unit, allowing the audio signal outputted to be played by the loudspeaker unit, wherein increment or decrement of playing volume of the loudspeaker unit corresponds in magnitude to variation of the audio signal.

7. The system for adjusting playing volume automatically according to ambient sound of claim 1, wherein the audio frequency module is electrically connected to a display device, allowing the audio signal outputted to be played by a loudspeaker unit of the display device, wherein increment or decrement of playing volume of the loudspeaker unit corresponds in magnitude to variation of the audio signal.

8. A set top box (STB) having the system of claim 1.

9. A method for adjusting playing volume automatically according to ambient sound, comprising the steps of:
retrieving, by a volume control unit, a sensing signal and a current time data generated by a volume sensing unit and a time data unit, respectively, and an audio variation data stored in a volume adjustment database; and
determining, by the volume control unit and according to comparison between the currently retrieved sensing signal and audio variation data, whether the audio variation data and playing volume should be currently adjusted, and generating, according to a result of the determining, a control signal for controlling variation of an audio signal outputted by an audio frequency module in real time.

10. The method for adjusting playing volume automatically according to ambient sound of claim 9, wherein the audio variation data comprises at least a predetermined time and at least a decibel level corresponding to the predetermined time.

11. The method for adjusting playing volume automatically according to ambient sound of claim 10, wherein the sensing signal has at least an external decibel level.

12. The method for adjusting playing volume automatically according to ambient sound of claim 11, wherein the audio variation data is adjusted upon determination by the volume control unit that the external decibel level of the sensing signal is beyond the decibel level of the audio variation data.

13. The method for adjusting playing volume automatically according to ambient sound of claim 11, wherein the audio variation data is not adjusted upon determination by the volume control unit that the external decibel level of the sensing signal is not beyond the decibel level of the audio variation data.

14. The method for adjusting playing volume automatically according to ambient sound of claim 10, wherein the playing volume is not adjusted upon determination by the volume control unit that the current time data is not beyond the predetermined time.

15. The method for adjusting playing volume automatically according to ambient sound of claim 10, wherein the playing volume is adjusted upon determination by the volume control unit that the current time data is beyond the predetermined time.
